(19) United States
(12) Patent Application Publication
(10) Pub. No.: US 2010/0195686 A1
(43) Pub. Date: Aug. 5, 2010

(54) Quantum cascade detector type device with high injector

(75) Inventor: Mathieu Carras, Gentilly (FR)

Correspondence Address: Damon M. Thurston, P.O. Box 3140, Monterey, CA, 93942, US

(73) Assignee: Thales, Neuilly Sur Seine (FR)

(21) Appl. No.: 12/497,843

(22) Filed: Jul. 6, 2009

(30) Foreign Application Priority Data
Jul. 4, 2008 (FR) 08 03812

(51) Int. Cl. H01S 5/34

(52) U.S. Cl. 372/45.012

(57) ABSTRACT

The invention relates to a quantum cascade device of detector type comprising two electrodes for applying a control electrical field, and a waveguide positioned between the two electrodes, said device comprising a gain region made up of a plurality of layers and comprising alternating strata of a first type each defining a quantum barrier and strata of a second type each defining a quantum well, each layer of the gain region comprising an injection barrier exhibiting an injection subband of charge carriers with a lower energy level called injector level (i) and an active area, said active area being made of a set of pairs of strata made from semiconductive materials so that each of the wells has at least one upper subband called third subband (3), a middle subband called second subband (2) and a bottom subband called first subband (1), the potential difference between the third and second subbands being such that the transition of an electron from the third subband to the second subband emits an energy corresponding to that needed for the emission of a photon, characterized in that:
the active area also has a fourth subband (4) situated above the third subband;
said fourth subband being such that, in the absence of any electrical field applied to the electrodes, the injector level of the injection barrier is less than the level of said fourth subband and greater than the level of the third subband and that, in the presence of a field applied to the electrodes, the charge carrier injector level (i) becomes greater than or equal to the level of the fourth subband, so as to generate a rapid relaxation phenomenon between the injector level and the fourth subband, the fourth subband being at a distance energy-wise from the third subband allowing an optical phonon relaxation.

### PRIORITY CLAIM

This application claims priority to French Patent Application Number 08 03812, entitled Dispositif de type détecteur à cascades quantiques à injecteur haut, filed on Jul. 4, 2008.

The field of the invention is that of quantum cascade devices in the mid-infrared and typically in the 3-10 micron wavelengths, generated from semiconductor materials III-V.

### BACKGROUND OF THE INVENTION

Generally, quantum cascade lasers are known that comprise two electrodes for applying a control electrical field, a waveguide positioned between the electrodes and a structure comprising a gain region made up of a plurality of layers that comprise alternating strata of a first type each defining a quantum barrier and strata of a second type each defining a quantum well, these strata being made of first and second semiconductor materials, respectively constituting barriers and wells.

The structure also comprises two optical containment layers arranged either side of the gain region. These lasers are obtained by a complex series of steps of layer deposition on a monocrystalline substrate and steps of chemical or physical-chemical etching designed to form the diffraction array and structure the laser.

The constituent materials of the barriers and of the wells are chosen so that they present a mesh that is equal to that of the substrate, so as to retain the monocrystalline structure throughout the thickness of the laser.

Generally, throughout the description, a stratum is defined as a unitary layer of uniform composition of small thickness and a layer as being a set of strata providing one and the same function.

The crystalline potential difference of the first and second materials respectively forming the strata of first and second types defines, by quantization, one or more two-dimensional states called energy levels or subbands. A pattern made up of a plurality of these pairs of strata constitutes the gain medium of the laser and is repeated periodically N times.

Each of the periods comprises an active area and an energy relaxation area. The application of an electrical field to the terminals of the electrodes generates a charge carrier current notably within the gain region. The emission of laser radiation is generated by the transition of charge carriers in the active area from a first to a second subband. This phenomenon, called intersubband transition, is accompanied by the emission of a photon.

The operation of this type of laser is based on the occurrence of electronic transitions between different permitted levels of energy within the conduction band of the semiconductive quantum structures and by the transition of charge carriers in the active area from a first to a second subband, accompanied by the emission of optical phonons.

FIG. 1 illustrates an exemplary quantum cascade laser according to the state of the art having discrete energy levels called subbands. The figure shows the different subbands and the probability of presence of charge carriers on said subbands respectively referenced i, 3, 2 and 1. The subband i corresponds to a so-called injection subband comprising a large quantity of electrons conventionally injected by doping. Under the action of an appropriate electrical field, electrons present on this subband i are made to switch over to the upper subband 3, said electrons by electronic transition to the subband 2, generate the emission of an optical phonon, the charge carriers of the subband 2 then being able to be extracted from a bottom extraction subband 1. This type of laser is, however, limited by the fact that the carriers introduced by the doping of the structure for the electronic transport introduce optical losses and therefore degrade the laser threshold. It is therefore important to optimize the number of useful carriers in the structure.

### BRIEF SUMMARY OF THE INVENTION

These devices are currently known as laser devices; the present invention proposes to use this type of quantum cascade device as a detector.

This is why the subject of the present invention is a novel type of detector-type quantum cascade device comprising an additional subband, the position of which is optimized to limit the doping needed to obtain the laser effect.

More specifically the subject of the present invention is a quantum cascade device of detector type comprising two electrodes for applying a control electrical field, and a waveguide positioned between the two electrodes, said device comprising a gain region made up of a plurality of layers and comprising alternating strata of a first type each defining a quantum barrier and strata of a second type each defining a quantum well, each layer of the gain region comprising an injection barrier exhibiting an injection subband of charge carriers with a lower energy level called injector level and an active area, said active area being made of a set of pairs of strata made from semiconductive materials so that each of the wells has at least one upper subband called third subband (3), a middle subband called second subband and a bottom subband called first subband, the potential difference between the third and second subbands being such that the transition of an electron from the third subband to the second subband emits an energy corresponding to that needed for the emission of a photon, characterized in that:
the active area also has a fourth subband situated above the third subband;
said fourth subband being such that, in the absence of any electrical field applied to the electrodes, the injector level of the injection barrier is less than the level of said fourth subband and that, in the presence of a field applied to the electrodes, the charge carrier injector level (i) becomes greater than or equal to the level of the fourth subband, so as to generate a rapid relaxation phenomenon between the injector level and the fourth subband, the fourth subband being at a distance energy-wise from the third subband allowing an optical phonon relaxation,

and in that, in the absence of field applied to the electrodes, the third subband is situated at a higher level than that of the injection subband, enabling this subband to provide an electron extraction function under the action of a photon absorption.

According to a variant of the invention, the fourth subband and the third subband exhibit an energy difference of approximately a few tens of meV.

The subject of the invention is thus a quantum cascade device operating as a detector without voltage applied to the electrodes, the third subband being situated at a level substantially equal to that of the injection subband, enabling this subband to provide an electron extraction function under the action of a photon absorption.

According to a variant of the invention, the device comprises a substrate of InP or GaAs or GaSb or InAs type.

According to a variant of the invention, the first semiconductor material is of AlGaAs or AlInAs or AlSb or InAs or AlGaSb type.

According to a variant of the invention, the second semiconductor material is of InGaAs or AlGaAs or AlSb or InAs or AlGaSb type.

### BRIEF DESCRIPTION OF THE SEVERAL VIEWS OF THE DRAWINGS

The invention will be better understood and other benefits will become apparent from reading the description that follows, given by way of nonlimiting example and from the appended figures in which:

FIG. 1 illustrates an exemplary quantum cascade laser according to the known art;

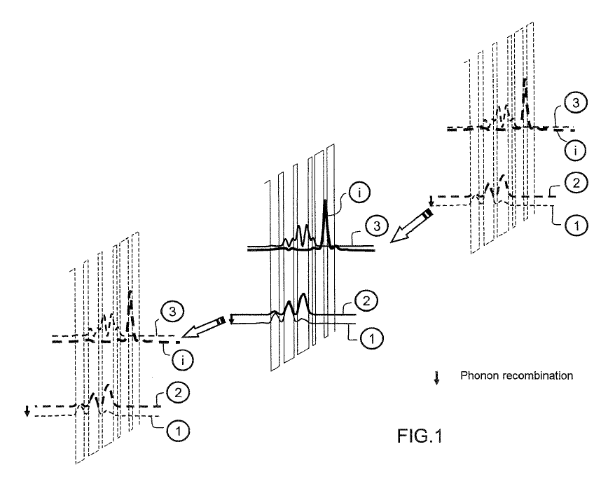

FIG. 2 illustrates an exemplary quantum cascade device according to the invention operating as a detector with no electrical field applied.

### DETAILED DESCRIPTION OF THE INVENTION

Advantageously, the inventive device behaves like a detector device in the absence of any applied electrical field.

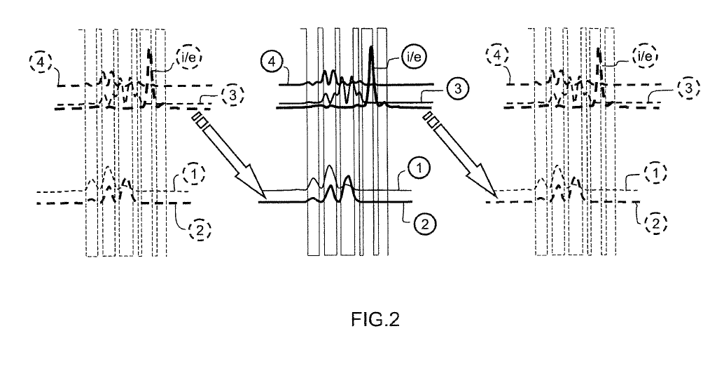

To this end, FIG. 2 illustrates the position of the different subbands i, 4, 3, 2 and 1. In the absence of any applied field, the subband 2 is positioned at a level below that of the subband 1.

Generally, when photons of energy E=hv are absorbed by the quantum cascade device, charge carriers are made to pass from the subband 2 to the subband 3, the collection by an external electrical circuit of these electrons being able to be implemented at the level of the third subband to which they have been carried by infrared lighting, so enabling the detection of this lighting. According to the principle that is then used, the electrodes situated on a bottom level subband are carried to an upper level subband, enabling them to be extracted.

According to the inventive device, the subband corresponding to the injector level i becomes the extractor level. In practice, by photon absorption, electrons carried to the subband 3 can be extracted at the level of the injector subband as revealed in FIG. 2, since the latter is situated at a lower energy level than the subband 3. The arrow shown illustrates the relaxation of the carriers to the level 2 of the next cascade, leading to the displacement of the photon-excited electron.

1. Quantum cascade device of detector type comprising two electrodes for applying a control electrical field, and a waveguide positioned between the two electrodes, said device comprising a gain region made up of a plurality of layers and comprising alternating strata of a first type each defining a quantum barrier and strata of a second type each defining a quantum well, each layer of the gain region comprising an injection barrier exhibiting an injection subband of charge carriers with a lower energy level called injector level (i) and an active area, said active area being made of a set of pairs of strata made from semiconductive materials so that each of the wells has at least one upper subband called third subband (3), a middle subband called second subband (2) and a bottom subband called first subband (1), the potential difference between the third and second subbands being such that the transition of an electron from the third subband to the second subband emits an energy corresponding to that needed for the emission of a photon, wherein:
the active area also has a fourth subband (4) situated above the third subband;
said fourth subband being such that, in the absence of any electrical field applied to the electrodes, the injector level of the injection barrier is less than the level of said fourth subband and that, in the presence of a field applied to the electrodes, the charge carrier injector level (i) becomes greater than or equal to the level of the fourth subband, so as to generate a rapid relaxation phenomenon between the injector level and the fourth subband, the fourth subband being at a distance energy-wise from the third subband allowing an optical phonon relaxation,
and in that, in the absence of field applied to the electrodes, the third subband is situated at a higher level than that of the injection subband, enabling this subband to provide an electron extraction function under the action of a photon absorption.

2. Quantum cascade device according to claim 1, wherein the fourth subband and the third subband exhibit an energy difference of approximately a few tens of meV.

3. Quantum cascade device according to one of claim 1 or 2, wherein it emits a laser emission in the infrared under the action of an electrical field applied to the electrodes.

4. Quantum cascade device according to one of claims 1 to 2, wherein comprising a substrate of InP or GaAs or GaSb or InAs type.

5. Quantum cascade device according to one of claims 1 to 2, wherein the first semiconductor material is of AlGaAs or AlInAs or AlSb or InAs or AlGaSb type.

6. Quantum cascade device according to one of claims 1 to 2, wherein the second semiconductor material is of InGaAs or AlGaAs or AlSb or InAs or AlGaSb type.
